(19) United States
(12) Patent Application Publication
(10) Pub. No.: US 2026/0047348 A1
(43) Pub. Date: Feb. 12, 2026

(54) SEMICONDUCTOR DEVICE WITH OXIDE-BASED HETEROSTRUCTURE AND METHOD FOR THE SAME

(71) Applicants: University of Pittsburgh - Of the Commonwealth System of Higher Education, Pittsburgh, PA (US); Wisconsin Alumni Research Foundation, Madison, WI (US)

(72) Inventors: Jeremy Levy, Pittsburgh, PA (US); Chang-Beom Eom, Madison, WI (US); Ruiqi Sun, Madison, WI (US); Ahmed Osama Omran, Pittsburgh, PA (US)

(73) Assignees: University of Pittsburgh - Of the Commonwealth System of Higher Education, Pittsburgh, PA (US); Wisconsin Alumni Research Foundation, Madison, WI (US)

(21) Appl. No.: 19/292,622

(22) Filed: Aug. 6, 2025

Related U.S. Application Data
(60) Provisional application No. 63/680,380, filed on Aug. 7, 2024.

(51) Int. Cl. H10N 60/10; B82Y 10/00; H10N 60/01

(52) U.S. Cl. CPC H10N 60/11; H10N 60/01; H10N 60/128; B82Y 10/00

(57) ABSTRACT

A structure includes a semiconductor substrate. The structure further includes a first oxide structure disposed above the semiconductor substrate and a second oxide structure disposed above the first oxide structure and configured to form a conductive path at an interface between the first oxide structure and the second oxide structure. The structure additionally includes a conducting structure extending from the interface through the second oxide structure. The conducting structure is configured such that in response to a voltage being applied to the conducting structure, a charge carrier is generated below the second oxide structure along the conductive path.

### CROSS-REFERENCE TO RELATED APPLICATION

This application claims priority to and the benefit of U.S. Provisional Application No. 63/680,380, filed Aug. 7, 2024, the entire contents of which are incorporated herein by reference for all purposes.

### STATEMENT REGARDING FEDERALLY SPONSORED RESEARCH OR DEVELOPMENT

This invention was made with government support under Contract No. DE-FG02-06ER46327 awarded by the Department of Energy and Contract Nos. N00014-20-1-2844 and N00014-21-1-2537 awarded by the Office of Naval Research. The government has certain rights in the invention.

### TECHNICAL FIELD

This disclosure relates to semiconductor devices, particularly to semiconductor devices with oxide-based heterostructures.

### BACKGROUND

There is a need for semiconductor devices with enhanced performance, for example, for applications in advanced silicon computing.

### SUMMARY

The present disclosure relates to techniques for semiconductor devices with an oxide-based heterostructure. According to the present disclosure, a semiconductor structure can include an oxide-based heterostructure, which can be configured to generate and control a charge carrier flow.

One aspect of the present disclosure relates to a structure. The structure includes a semiconductor substrate, a first oxide structure disposed above the semiconductor substrate, a second oxide structure disposed above the first oxide structure and configured to form a conductive path at an interface between the first oxide structure and the second oxide structure, and a conducting structure extending from the interface through the second oxide structure, the conducting structure being configured such that, in response to a voltage being applied to the conducting structure, the conducting structure cases a charge carrier to be generated below the second oxide structure along the conductive path.

In some examples, the first oxide structure includes La, Al, and O, and the second oxide structure includes Sr, Ti, and O. In some examples, the first oxide structure and the second oxide structure form a freestanding membrane structure. In some examples, the conducting structure is further configured such that in response to the voltage being applied to the conducting structure, electrons are controlled at a single electron level. In some examples, the conducting structure is further configured such that in response to the voltage being applied to the conducting structure, the electrons of the charge carrier may be individually controllable. In some examples, the conductive path includes a secondary conductive path to control the electrons. In some examples, a first portion and a second portion of the semiconductor substrate adjacent to a bottom surface of the first oxide structure are doped to form a source/drain structure configured to provide the charge carrier. In some examples, the structure is configured as a field effect transistor (FET), and the FET is in an off state in response to the voltage being lower than a threshold voltage, and the FET is in an on state in response to the voltage being higher than the threshold voltage. In some examples, the first oxide structure is thinner than the second oxide structure. In some examples, the charge carrier is a two-dimensional electron gas.

Another aspect of the present disclosure relates to a device. The device includes a substrate, a La-based structure disposed above the substrate, a Sr-based structure disposed above the La-based structure, and a source structure and a drain structure adjacent to a bottom surface of the La-based structure. An interface between the La-based structure and the Sr-based structure is configured to form a conductive path in response to a signal to cause a transition of an electrical property of the interface. In response to a voltage applied to the conductive path, the conductive path is configured to cause a charge carrier flow to be generated below the La-based structure.

In some examples, the substrate includes one of: (i) silicon, II-VI compounds, or III-V compounds, (ii) an electronic device, a photonic device, an optoelectronic device, a quantum device, or a single electron device, and (iii) a two-dimensional (2D) material or a flexible material. In some examples, the programming signal is generated by electron beam lithography or atomic force microscopy lithography. In some examples, the charge carrier includes electrons or holes. In some examples, the conductive path includes a secondary conductive path to control the charge carrier. In some examples, a thickness of the Sr-based structure is thinner than about 50 nm. In some examples, the La-based structure is thinner than the Sr-based structure. In some examples, in response to the signal being provided on a portion of the interface at a first voltage level, the portion becomes conducting, and in response to the signal being provided on the portion of the interface at a second voltage level, the portion becomes insulating. In some examples, a portion of the interface is configured to, (i) in response to the signal being provided on the portion of the interface at a first voltage level, have a first conductivity, and (ii) in response to the signal being provided on the portion of the interface at a second voltage level, have a second conductivity, wherein the second conductivity is lower than the first conductivity. In some examples, the La-based structure is stacked on the substrate through a van der Waals force. In some examples, the device is a field effect transistor (FET), and the La-based structure is to serve as a barrier of the FET. In some examples, the La-based structure and the Sr-based structure forms a freestanding membrane structure configured to be transferrable to another substrate.

Another aspect of the present disclosure relates to a method. The method includes providing a first substrate, forming a Sr-based structure on the first substrate, forming a La-based structure on the Sr-based structure, selectively etching to remove, from the first substrate, a heterostructure including the Sr-based structure and the La-based structure, manipulating the heterostructure, and integrating the heterostructure onto a second substrate through a van der Waals force.

In some examples, the method includes epitaxially growing the Sr-based structure and the La-based structure. In some examples, the method includes selectively etching the heterostructure and retrieving the heterostructure prior to manipulating the heterostructure. In some examples, the first substrate includes a sacrificial layer on which the Sr-based structure is formed, and the selectively etching includes etching the sacrificial layer. In some examples, the manipulating includes retrieving the removed heterostructure using a wire loop, inverting the retrieved heterostructure using the wire loop, and positioning, using a micromanipulator system, the inverted heterostructure on the second substrate.

Another aspect of the present disclosure relates to a method. The method includes providing a semiconductor structure on which a heterostructure is formed, the heterostructure including a La-based structure and a Sr-based structure formed thereon, applying, on the heterostructure, a signal to cause a transition of an electrical property of an interface between the La-based structure and the Sr-based structure, forming a conductive path at the interface according to an application of the programming signal, applying, on the conductive path, a voltage, and generating a charge carrier flow below the La-based structure, along the conductive path.

In some examples, the semiconductor structure includes one of silicon, II-VI compounds, or III-V compounds. In some examples, the programming signal is generated by electron beam lithography or atomic force microscopy lithography. In some examples, the charge carrier includes electrons or holes. In some examples, the method includes controlling the electrons at a single electron level. In some examples, the heterostructure is freestanding from the semiconductor structure.

Both the foregoing summary and the following description of the drawings and detailed description are exemplary and explanatory. They are intended to provide further details but are not to be construed as limiting. Other objects, advantages, and novel features will be readily apparent to those skilled in the art from the following detailed description.

### BRIEF DESCRIPTION OF THE DRAWINGS

Aspects of the present disclosure can be understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a schematic diagram of an example of a semiconductor device, in accordance with some embodiments.

FIG. 2 illustrates a schematic diagram of an example of a semiconductor device, in accordance with some embodiments.

FIG. 3 illustrates a schematic diagram of an example of a semiconductor device, in accordance with some embodiments.

FIG. 4 illustrates a schematic diagram of an example of a semiconductor device, in accordance with some embodiments.

FIGS. 5A and 5B illustrate schematic diagrams of an example of a semiconductor device, in accordance with some embodiments.

FIGS. 6A and 6B illustrate schematic diagrams of an example of a semiconductor device, in accordance with some embodiments.

FIGS. 7A, 7B, 7C, and 7D illustrate plots of waveforms associated with an example semiconductor device, in accordance with some embodiments.

FIG. 8A illustrates a schematic diagram of an example of a semiconductor device, in accordance with some embodiments.

FIG. 8B illustrates a schematic diagram of an example of a semiconductor device, in accordance with some embodiments.

FIG. 9 illustrates a schematic diagram of an example of a semiconductor device, in accordance with some embodiments.

FIG. 10 illustrates a flowchart of an example method for a semiconductor device, in accordance with some embodiments.

FIG. 11 illustrates a flowchart of an example method for a semiconductor device, in accordance with some embodiments.

FIG. 12 illustrates a schematic flow diagram of an example method for a semiconductor device, in accordance with some embodiments.

FIG. 13 illustrates a schematic flow diagram of an example method for a semiconductor device, in accordance with some embodiments.

FIG. 14A illustrates an example configuration of an inverted membrane that has been transferred onto a second substrate, in accordance with some embodiments.

FIG. 14B illustrates an alternative example configuration of the inverted membrane of FIG. 14A, in accordance with some embodiments.

FIG. 15 illustrates example applications of an inverted membrane across various material platforms, in accordance with some embodiments.

### DETAILED DESCRIPTION

Integrating an oxide-based heterostructure into a semiconductor device can be challenging due to lattice mismatches, which may lead to structural defects and high sheet resistance. For instance, forming a heterostructure with LaAlO₃ (LAO) on SrTiO₃ (STO) and integrating it onto SiO₂/Si substrates is difficult because of lattice mismatches between STO and the substrate, resulting in high sheet resistance. Consequently, such structures may not be feasible for efficient semiconductor or quantum processing applications.

The present disclosure provides techniques for semiconductor devices incorporating oxide heterostructures. According to this disclosure, a La-based oxide structure, such as LAO, can be disposed above a semiconductor substrate like silicon, for example through van der Waals forces, while a Sr-based oxide structure, such as STO, can be placed on top of it. In some examples, the heterostructure can be formed by forming the La-based structure on the Sr-based structure, manipulating it (e.g., inverting by flipping, adjusting positions), and then integrating the inverted structure onto the substrate. Such inversion allows for stacking sequences that are otherwise unachievable through direct epitaxial growth, limited by kinetic constraints such as cation interdiffusion and thermal expansion mismatch. The stacking order can play a significant role in determining interfacial electronic properties. For example, while the LAO/STO interface typically exhibits n-type conductivity, the inverted (e.g., flipped) STO/LAO interface, with a single-terminated LAO substrate, can be insulating due to polarity differences. Thus, high-quality, inverted oxide heterostructures are useful for tailoring interfacial functionality and advancing next-generation electronic devices, including quantum electronics and two-dimensional materials. Additionally, positioning the La-based structure in contact with the substrate, such as Si, can result in a sharp interface with a lower defect density, thereby reducing leakage and improving device performance. Furthermore, the heterostructure described herein can be a freestanding membrane, and can be transferrable over different device regions and/or platforms.

In some examples, a programming signal can be applied to induce a transition in electrical property at a buried interface between the La-based and Sr-based oxide structures, thus creating a programming or reconfigurable conductive path. This conductive path can serve as a local gate to control the underlying device. Applying a voltage to the conductive path can generate charge carriers below the La-based oxide structure along the conductive path. In some instances, the conductive path can be configured to generate or control electrons at the single electron level. This capability enables the integration of STO/LAO-based heterostructure with various electronic platforms, such as silicon devices for advanced silicon computing, including quantum computing. By using programming signals for high-resolution patterning, the semiconductor devices can be configured as programmable or reconfigurable nanodevices for storing and gating single electrons and their spins. For example, the device can be implemented as a programmable or reconfigurable device, such as field-effect transistors (FETs) or single-electron transistors (SETs), which enable tunable gating behavior and enhanced performance. For example, the STO/LAO structure may include a programmable, reprogrammable, or reconfigurable top electrode that facilitates accumulation of electrons in the underlying layer, such as the Si substrate or device region. In some embodiments, the STO layer can function as a functional layer configured to form the two-dimensional electron gas (2DEG), while the LAO layer (e.g., which can be only a few nanometers thick) is positioned adjacent to the substrate, serving as a gate dielectric. This arrangement supports high-resolution gate patterning and effective field effect modulation, based on LAO's wider bandgap in comparison to STO. Additionally, the techniques described herein can be applied to programmable quantum platforms. For instance, silicon patterning with spin-on doping, such as phosphorus, facilitates the application of silicon spin qubits for quantum sensing, including stacks like hexagonal boron nitride, graphene, and hexagonal boron nitride quantum dots. Thus, these techniques, with high-resolution patterning of quantum devices, can offer a quantum material host system for storing and processing quantum information.

While the structures described above improve advanced nanoelectronic and quantum applications, certain challenges remain, including accurately aligning and transferring the freestanding membrane onto the host platform target region, such as the substrate or device region, and inverting the heterostructure stack while preserving its structural and electronic integrity. For precise alignment, the functional interfaces of the membrane need to overlap predefined device regions (e.g., gate channels or contact areas), as even minor misalignments can compromise device performance or yield. Moreover, the membrane needs careful manipulation to avoid cracks, wrinkles, or contamination that may degrade crystallinity or interfacial quality. These challenges are exacerbated by the need to maintain nanoscale thickness control, preserve clean interfaces, and manage mechanical stresses during the transfer and integration process.

To address these challenges, the present disclosure provides techniques for forming inverted, freestanding oxide heterostructures (e.g., STO/LAO membranes). The techniques may include epitaxially growing the heterostructure on a sacrificial layer and then selectively etching the sacrificial layer to release the membrane. This released membrane can be inverted and transferred onto a target host, for example, through van der Waals bonding. Such an approach allows the fabrication of stacked sequences that are otherwise inaccessible by direct growth while maintaining high crystallinity, nanoscale thickness control, and clean interfacial quality. By separating growth and integration steps, this approach avoids thermal expansion mismatch and cation interdiffusion issues related to direct epitaxy on dissimilar materials. Furthermore, the technique enables a thin layer of the membrane (e.g., LAO) to be placed directly in contact with the host, serving as an effective gate dielectric with a wide bandgap and supporting high-resolution patterning.

With the foregoing in mind, the figures and description below illustrate various examples of structures and methods for semiconductor devices incorporating oxide heterostructures. It should be noted that the figures and description below are non-limiting examples and can be implemented as any of various other configurations while remaining within the scope of the present disclosure.

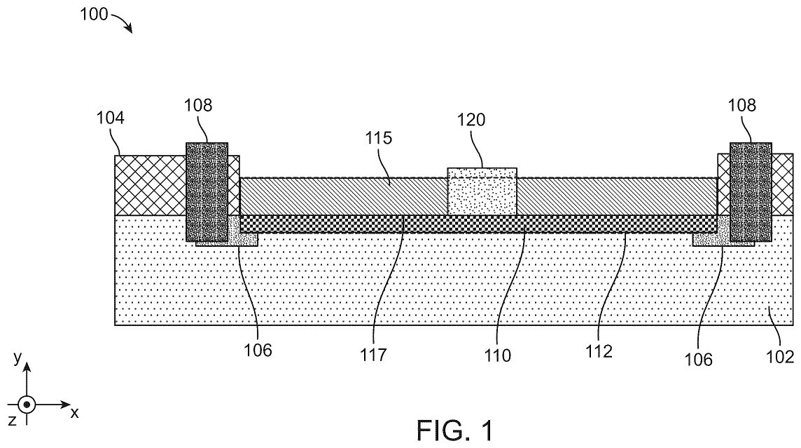

FIG. 1 illustrates a schematic diagram of an example of a semiconductor device 100, in accordance with some embodiments. The device 100 includes a substrate 102, an isolation dielectric 104, source and drain (S/D) structures 106, electrode structures 108, a first structure 110, a second structure 115, and a conducting structure 120. Shown in FIG. 1 is a non-limiting example of the device 100. In some examples, the device 100 can include more, fewer, or different components than shown in FIG. 1.

The substrate 102 can be or include a semiconductor substrate. The substrate 102 can include, but not limited to, silicon, II-VI compounds, III-V compounds, or any other semiconductor substrate on which the first structure 110 can be provided. For example, the substrate 102 can include gallium arsenide, a III-V heterostructure, etc. In some examples, the substrate 102 can be or include a multi-layer structure, for example, including but not limited to, an insulating layer (e.g., silicon oxide), a doped layer (e.g., p-type silicon, n-type silicon, etc.), etc. It should be understood that “substrate” as used herein generically refers to an object being processed. The substrate 102 can include any material portion or structure of a device, particularly a semiconductor or other electronics device, and can, for example, be a base substrate structure, such as a semiconductor wafer, reticle, or a layer on or overlying a base substrate structure such as a thin film. Thus, the substrate 102 is not limited to any particular base structure, underlying layer or overlying layer, patterned or un-patterned, but rather, is contemplated to include any such layer or base structure, and any combination of layers and/or base structures. Shown in FIG. 1 and described herein are a non-limiting example for illustrative purposes.

The S/D structures 106 can be or include a semiconductor structure to serve as a source and drain of a semiconductor device. In some examples, the S/D structures 106 can be or include a doped region of the substrate 102. For example, a portion of the substrate 102 can be doped (e.g., n-type, p-type) to form the S/D structures 106. When the substrate 102 is silicon, for example, the S/D structures 106 can be doped with one or more dopants. For example, the S/D structures 106 can be silicon doped with phosphorus. In some examples, the S/D structures 106 can be or include a semiconductor structure that is epitaxially grown and is different from the substrate 102. In some examples, as shown in FIG. 1, the S/D structures 106 can be formed adjacent to a bottom surface of the first structure 110. The S/D structures 106 can be configured such that one of the S/D structures 106 is formed at a first end of the first structure 110 while being in contact with the bottom surface of the first structure 110. The other of the S/D structures 106 can be formed at a second end of the first structure 110 while being in contact with the bottom surface of the first structure 110. That is, the S/D structures 106 can be configured to form a channel below the first structure 110. In some examples, the S/D structures 106 can be connected to the electrode structures 108.

The electrode structures 108 can be or include any conducting structure to electrically contact the S/D structures 106. The electrode structures 108 can be connected to a respective one of the S/D structures 106. In some examples, as shown in FIG. 1, the electrode structures 108 can be formed through the isolation dielectric 104 to electrically contact the S/D structures 106. The electrode structures 108 can be or include any conducting material, for example, a metal. Although depicted as one material, the electrode structures 108 can include one or more materials and/or one or more structures.

The first structure 110 can be or include a structure or layer configured to serve as a barrier between the second structure 115 and the substrate 102. In some examples, the first structure 110 can be or include an oxide structure disposed above the substrate 102. In some examples, the first structure 110 can be or include an oxide structure including La, Al, and O. For example, the first structure 110 can be LaAlO₃ (LAO). In some examples, the first structure 110 can be thinner than the second structure 115. In some examples, as shown, the first structure 110 can extend between the isolation dielectric 104 and/or the S/D structures 106. In some examples, an interface 112 vertically between the first structure 110 and the substrate 102 can be electrically isolated such that the interface 112 can serve as a channel when, for example, the device 100 is configured to operate as a field-effect transistor (FET) device.

The second structure 115 can be or include a structure or layer configured to control conductivity of the interface 112. In some examples, the second structure 115 can be or include an oxide structure disposed above the first structure 110. In some examples, the second structure 115 can be or include an oxide structure including Sr, Ti, and O. For example, the second structure 115 may be SrTiO₃ (STO). In some examples, the second structure 115 can be thicker than the first structure 110. In some examples, the second structure 115 may be thinner than about 50 nm. In other examples, the second structure 115 may have a thickness that enables a backside writing while balancing mechanical stability and patterning precision for high-resolution nanoelectronic applications. In some examples, as shown, the second structure 115 can extend between the isolation dielectric 104 while interfacing the first structure 110.

In some examples, a stacked structure (or sometimes referred to as “membrane”) of the first structure 110 and the second structure 115 can be configured to form a conductive path at an interface 117 between the first structure 110 and the second structure 115. In some examples, the interface 117 can be configured to form a conductive path in response to a signal to cause a transition of an electrical property of the interface 117. For example, the interface 117 can be configured to form the conductive path, which can be configured to change its conductivity (e.g., switching between a conducting state and an insulating state).

The conducting structure 120 can be or include any conducting structure or material to provide an electrical signal to the conductive path at the interface 117. In some examples, a voltage can be applied to the conductive path at the interface 117 through the conducting structure 120. In some examples, the conducting structure 10 can extend from the interface 117 through the second structure 115. In some examples, the device 100 can include a plurality of conducting structures 120 to access the conductive path at the interface 117.

In some examples, the first structure 110 and the second structure 115 can form a freestanding membrane structure. For example, the first structure 110 and the second structure 115 can form a STO/LAO membrane. In some examples, the first structure 110 can be stacked on the substrate 102 through a van der Waals force, as a freestanding membrane. In some examples, the lattice mismatch between the first structure 110 and the substrate 102 can be less than a predetermined range (e.g., that of silicon and LAO).

The device 100 can operate as a transistor device. For example, the device 100 can operate as a FET device. In some examples, the first structure 110 and the substrate 102 can be configured such that the interface 112 can serve as a channel for a FET device. The first structure 110 and the substrate 102 can be configured such that a lattice mismatch therebetween allows for the conductivity of the channel high enough for a device channel. In some examples, the first structure 110 can serve as a barrier of the FET device. In some examples, the conductive path formed at the interface 117 can serve as a gate. As a non-limiting example, in response to a voltage applied to the conducting structure 120, a charge carrier can be generated below the first structure 110 (e.g., at the interface 112) along the conductive path (e.g., formed at the interface 117). In some examples, the charge carrier flow can be generated below the first structure 110 (e.g., at the interface 112) between the S/D structures 106. The charge carrier can thereby flow through the channel formed at the interface 112. In some examples, the charge carrier may be a two-dimensional electron gas (2DEG). In some examples, electrons can be generated and controlled at a single electron level, enabling the device 100 to be implemented as a single electron transistor.

In some examples, the first structure 110 and the second structure 115 (e.g., the STO/LAO membrane) can serve as a programmable (and/or reconfigurable) material layer configured to control and/or modify the properties of the underlying material (e.g., the substrate 102) through the interface 112. For instance, the conductive path formed at the interface 117 can be reconfigured using a programming signal (e.g., electron beams, atomic force microscopy, etc.). In response to such programming signals, the conductive path can be selectively defined to modulate electronic characteristics of the material beneath the membrane (e.g., the substrate 102). In this manner, the membrane functions as a programmable layer, while the substrate 102 or other target region acts as a programmed material whose behavior is dynamically controlled. This programmed material can be reprogrammed and/or reconfigured based on different programming signals. This programmable-programmed architecture enables tunable and reconfigurable device configurations, supporting applications such as field-effect control, spatially defined doping, or interface engineering across a broad range of host material.

As described herein, the membrane formed by the first structure 110 and the second structure 115 can be integrated with a wide variety of host substrates beyond silicon, enabling broader applicability across different material platforms. For instance, the membrane may be transferred onto various electronic platforms and compound semiconductors, 2D materials, superconductors, or photonic substrates without the constraints associated with epitaxial lattice matching. This substrate compatibility supports heterogeneous integration of complex oxide functionality with diverse target systems, including but not limited to, quantum electronics, single-photon detection, and optoelectronics.

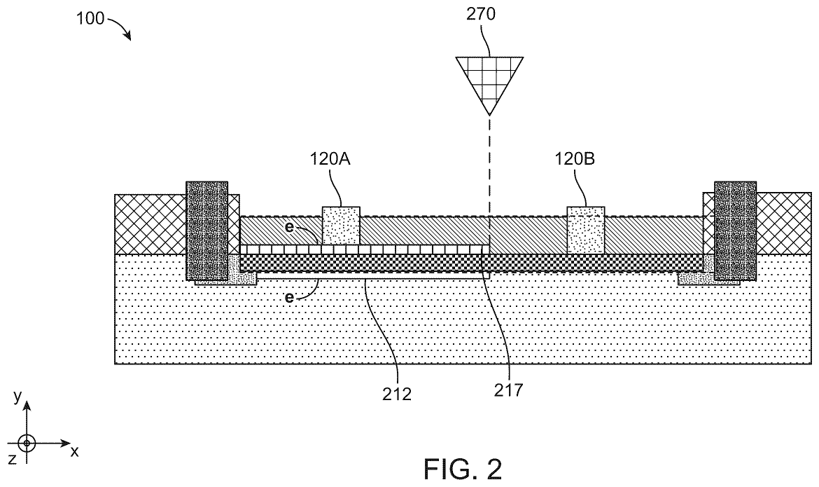

FIG. 2 illustrates a schematic diagram of an example of the semiconductor device 100, in accordance with some embodiments. More specifically, FIG. 2 shows the device 100, in which a conductive path 217 is formed in response to a programming signal 270, and a charge carrier flow 212 is formed according to the conductive path 217. As shown in FIG. 2, the conducting structure 120 of FIG. 1 can include a first conducting structure 120A and a second conducting structure 120B. The conductive path 217 and the charge carrier flow 212 shown in FIG. 2 are non-limiting examples.

The programming signal 270 can be any signal configured to cause a transition of an electrical property of the interface 117. In some examples, the programming signal 270 can be any signal that can configure, reconfigure, and/or program the electrical property of the interface 117. In some examples, the programming signal 270 can be or generated by electron beam (e-beam) or e-beam lithography. For example, the programming signal 270 can be generated by ultra-low voltage e-beam lithography (ULV-EBL). The ULV-EBL can be used to pattern the interface 117 and cause a transition of the electrical property of the interface 117 along the pattern. The ULV-EBL can enable patterning of buried layers (e.g., the interface 112), thereby facilitating the functional integration of the device 100. In some examples, the programming signal 270 can be generated by atomic force microscopy (AFM) lithography. For example, the programming signal 270 can be generated by conductive AFM (c-AFM) lithography. The programming signal 270 can be applied on the interface 117 along a predetermined path, which can define the conductive path 217 at the interface 117. The conductive path 217 can be configured to control the charge carrier flow 212.

As described herein, the interface 117 of the STO/LAO membrane (e.g., the first structure 110 and the second structure 115) can be reprogrammed into a conducting state through the programming signal 270. The backside writing process at the interface 117 enables electric tunability based on a nanowire-like conductive pathway between two electrodes.

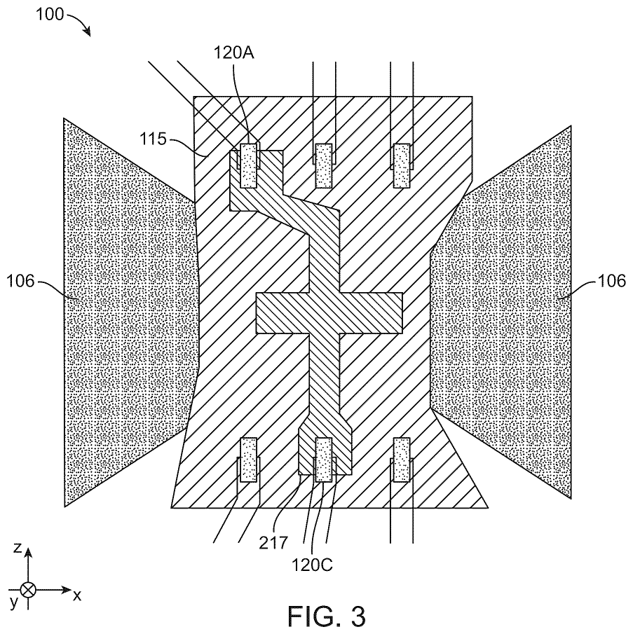

FIG. 3 illustrates a schematic diagram of an example of the semiconductor device 100, in accordance with some embodiments. More specifically, FIG. 3 shows a top view of a portion of the semiconductor device 100. As shown in FIG. 3, the conducting structure 120 of FIG. 1 can include a plurality of conducting structures, including the first conducting structure 120A and a third conducting structure 120C. Shown in FIG. 3 is a non-limiting example of the device 100. In FIG. 3, the device 100 may show more, fewer, or different components than shown in FIG. 1 and FIG. 3. FIG. 3 and components therein may not be scaled proportionally.

As shown in FIG. 3, the conductive path 217 can be formed at the interface 117 (e.g., between the first structure 110 and the second structure 115) as discussed above. In some examples, the conductive path 217 can serve as a gate, when the device 100 is configured to operate as a FET device. When a voltage is applied through the first conducting structure 120A and the third conducting structure 120C, the conductive path 217 can become conductive. Along the conductive path 217, the charge carrier flow 212 can be generated below the second structure 115 (e.g., at the interface 117). In some examples, the conductive path 217 can be designed, formed, or configured in various manners to generate and/or control the charge carrier flow 212. For example, the programming signal 270 can be applied to form the conductive path 217 in a way that controls the charge carrier flow 212.

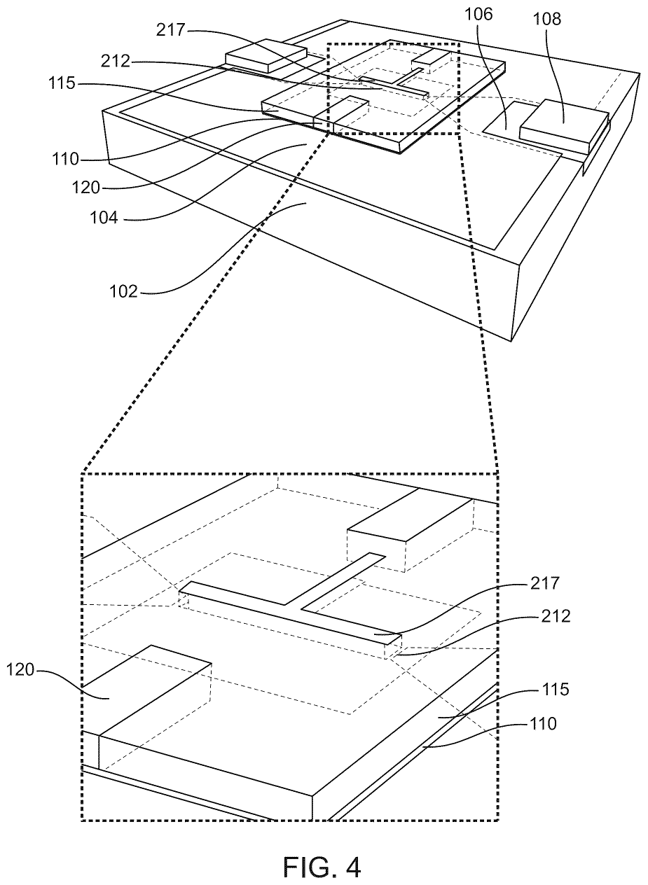

FIG. 4 illustrates a schematic diagram of an example of the semiconductor device 100, in accordance with some embodiments. FIG. 4 shows a top view of a portion of the semiconductor device 100. Shown in FIG. 4 is a non-limiting example of the device 100. In FIG. 4, the device 100 may show more, fewer, or different components than shown in FIG. 1 and FIG. 4. FIG. 4 and components therein may not be scaled proportionally.

Similar to the example of FIG. 3, the conductive path 217 can be formed at the interface 117 (e.g., between the first structure 110 and the second structure 115). In some examples, the conductive path 217 can form a first 2DEG at the interface 117. When a voltage is applied through the first conducting structure 120 (e.g., Au), the conductive path 217 can become conductive. Along the conductive path 217, the charge carrier flow 212 can be generated below the second structure 115 (e.g., at the interface 112) in response to the conductive path 217 being conductive. For example, a second 2DEG can be formed beneath the first structure 110. The conductive path 217 (e.g., the first 2DEG) can be designed, formed, or configured in various manners to generate and/or control the charge carrier flow 212 (e.g., the second 2DEG). For example, the programming signal 270 of FIG. 2 can be applied to form the conductive path 217, via which the charge carrier flow 212 can be controlled.

As shown in FIG. 4, the device architecture may include two semiconducting layers, the second structure 115 (e.g., STO) and the substrate 102 (e.g., Si), separated by the first structure 110 (e.g., LAO) acting as an insulating barrier. This configuration forms a MOS-like structure, in which the interface 117 (e.g., the STO/LAO interface) and the interface 112 (e.g., the LAO/Si interface) serve as electronically active regions. The first interface 117 can be selectively patterned by applying a programming signal (e.g., the programming signal 270), enabling spatial control over the conductive path 217. These patterned conductive path can act as local gate electrodes to electrostatically accumulate charge carriers (e.g., electrons) in the underlying substrate 102 (e.g., Si layer), with the first structure 110 (e.g., the LAO layer) serving as a gate dielectric due to its wide bandgap (e.g., 5.6 eV, where the particular bandgap varies with material selection). In this manner, reprogrammable and nanoscale gating of the silicon layer can be achieved using the top membrane (e.g., the first structure 110 and the second structure 115), enabling the creating of switchable channels and advanced field-effect behavior. In some examples, electrical contact to the conductive path 217 (e.g., the first 2DEG) can be established by performing argon ion (Ar+) milling to expose the interface 117, followed by Ti/Au metallization to define a contact. Electrical contact to the substrate 102 (e.g., to define a source/drain path) can be achieved using phosphorous spin-on doping.

As the substrate 102 may be or include various electronic and/or optoelectronic platforms, the semiconductor device 100 provides dynamic, reconfigurable control of such platforms through the membrane (e.g., the first structure 110 and the second structure 115).

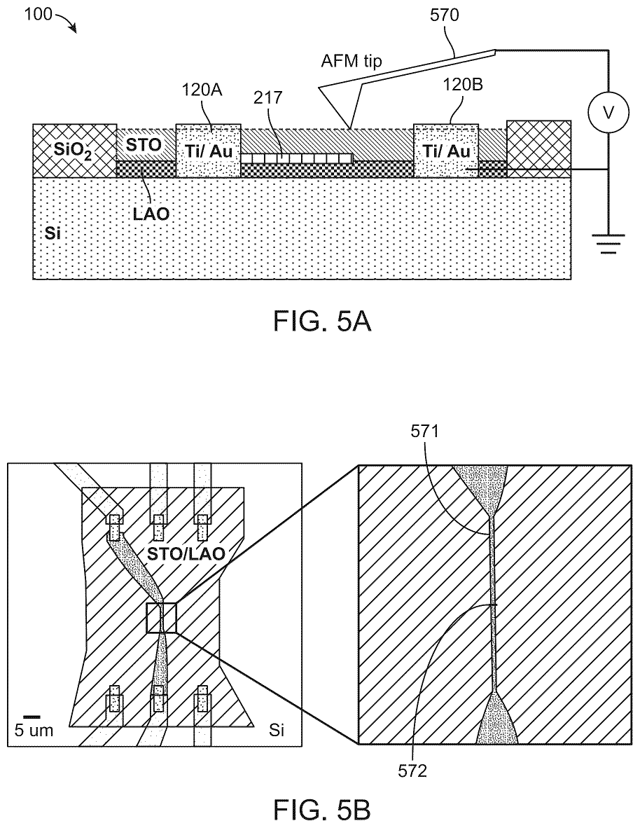

FIGS. 5A and 5B illustrate schematic diagrams of an example of the semiconductor device 100, in accordance with some embodiments. More specifically, FIG. 5A shows the device 100, in which the conductive path 217 is formed in response to a programming signal 570. In this example, the programming signal 570 is generated by c-AFM lithography. FIG. 5B shows a top view of the device 100 of FIG. 5A.

As shown in FIG. 5A, the c-AFM lithography can be used to program the conductive path 217 at the interface 117 (e.g., by changing an electrical property of the interface 117). In this example, a c-AFM tip biased with respect to the interface 117 can be scanned across the top surface of the second structure 115 (e.g., STO) in a contact mode to sketch nanostructures with spatially defined conductivity. The membrane (e.g., the first structure 110 and the second structure 115) can be initially insulating at the interface 117, such that conductivity can be selectively introduced by the programming signal 570. The c-AFM tip can be rastered over the top surface of the second structure 115 according to a lithographically defined pattern (e.g., shown in FIG. 5B). The programming signal 570 can include a first signal with a first tip bias and a second signal with a second tip bias to program the interface 117. For example, a first region 571 can be scanned with a positive tip bias (e.g., Vtip>0) and become conductive, while a second region 572 can be scanned with a negative tip bias (e.g., Vtip<0) and become insulating. Shown in FIG. 5B is a non-limiting example, and the programming signal 570 can be rastered over the top surface of the second structure 115 based on any lithographically defined patterns, thereby programming the interface 117. That is, the interface 117 can be configured to have a first conductivity (e.g., a value of conductivity for a conductor), in response to the programming signal 570 (e.g., the biased tip) at a first voltage level (e.g., positive). The interface 117 can be configured to have a second conductivity (e.g., a value of conductivity for an insulator; lower than the first conductivity), in response to the programming signal 570 (e.g., the biased tip) at a second voltage level (e.g., negative). In some examples, during programming, the conductance between the electrodes 120A, 120B can be monitored. In one example, a sharp conductance increase (e.g., to approximately 300 nS) can be observed upon completing a nanowire sketch using a positively biased AFM tip (e.g., Vtip=13 V), indicating formation of the conductive path 217.

The programming signal 570 can be configured to reverse, reprogram, or otherwise reconfigure the membrane (e.g., the interface between the first structure 110 and the second structure 115). In some implementations, by scanning the programming signal 570 (e.g., the AFM tip) across an existing conductive portion (e.g., a nanowire-shaped portion) with a negative bias (e.g., Vtip=−10 V), the conductive path 217 can be erased (e.g., become insulating). In some examples, this can be confirmed based on a conductance drop between the electrodes 120A, 120B. The ability to reversibly write and erase conductive features using the programming signal 570 (e.g., c-AFM lithography) enables reprogrammable gating architectures within the membrane, for example, by scanning with a negative tip bias to render the area insulating, followed by re-writing the gate pattern using a high positive tip bias (e.g., 25 V). Accordingly, the membrane as described herein can be reconfigured and reprogrammed, without re-fabrication, to control the substrate 102 (and/or any device platform below the membrane).

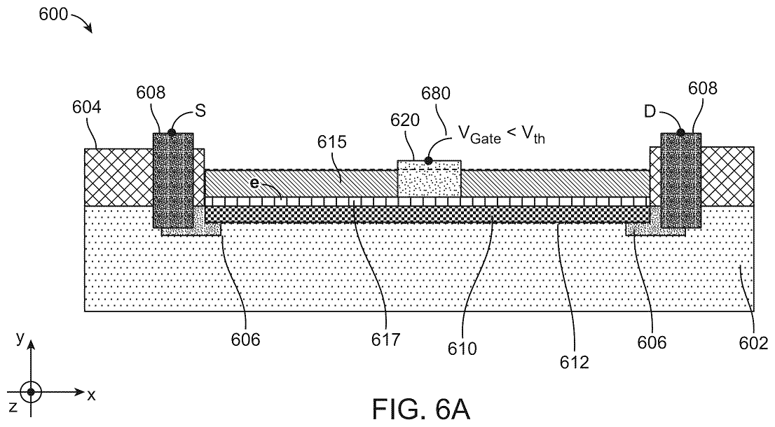

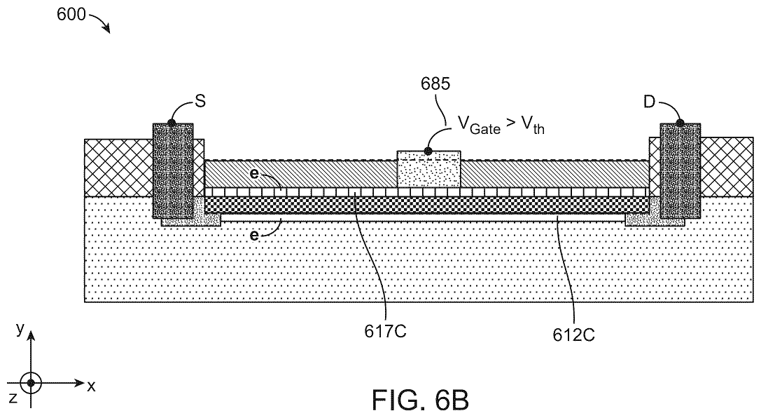

FIG. 6A illustrates a schematic diagram of an example of a semiconductor device 600, in accordance with some embodiments. More specifically, FIG. 6A shows the device 600 when a first gate signal (lower than the threshold voltage, VGate<Vth) 680 is applied. FIG. 6B illustrates a schematic diagram of the semiconductor device 600, in accordance with some embodiments. More specifically, FIG. 6B shows the device 600 when a second gate signal (higher than the threshold voltage, VGate>Vth) 685 is applied. The device 600 may be substantially similar to or incorporate features of the device 100. In some examples, the device 600 includes a substrate 602, an isolation dielectric 604, S/D structures 606, electrode structures 608, a first structure 610, an interface 612, a second structure 615, an interface 617, and a conducting structure 620, which can be substantially similar to or incorporate features of the substrate 102, the isolation dielectric 104, the S/D structures 106, the electrode structures 108, the first structure 110, the interface 112, the second structure 115, the interface 117, and the conducting structure 120, respectively. Shown in FIG. 6A and FIG. 6B is a non-limiting example of the device 600. In some examples, the device 600 can include more, fewer, or different components than shown in FIG. 6A and FIG. 6B. In some examples, referring to FIG. 6A and FIG. 6B, the substrate 602 is formed of Si, the isolation dielectric 604 is formed of SiO₂, the S/D structures 106 are formed as doped portions (e.g., doped with phosphorus to form n+Si) of the substrate 602, the electrode structures 608 are formed of Al (Si), the first structure 610 is formed of LAO, the second structure 615 is formed of STO, and the conducting structure 620 is formed of Au (STO).

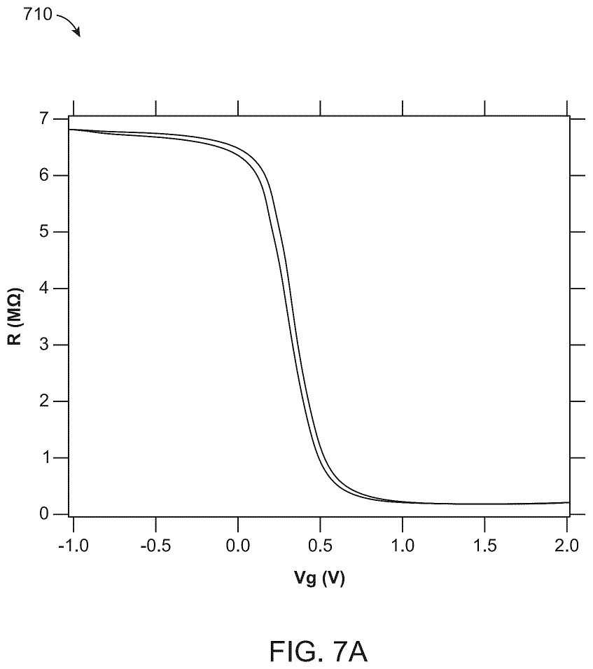

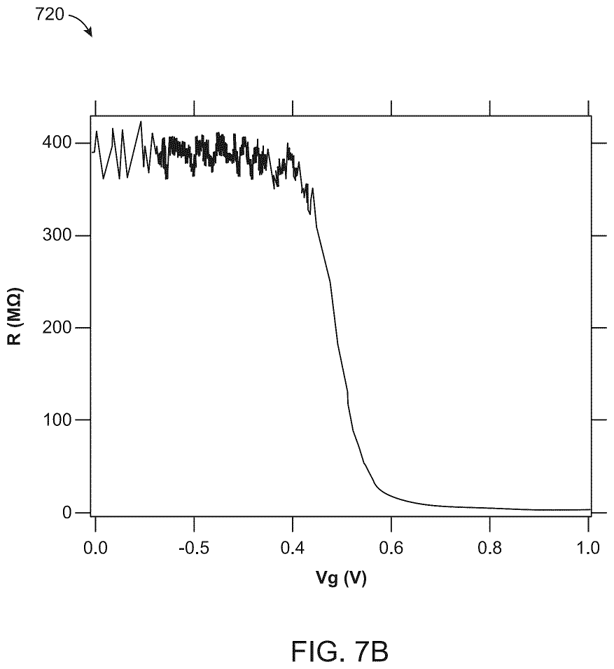

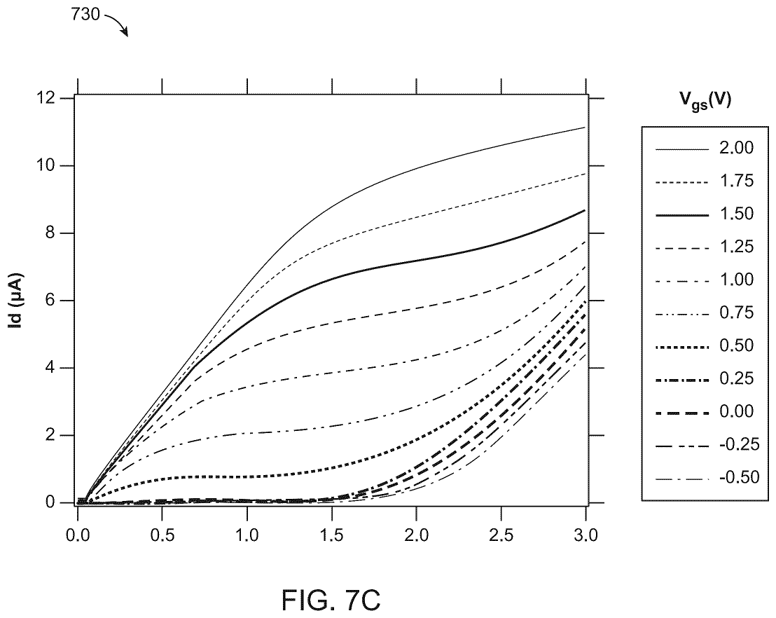

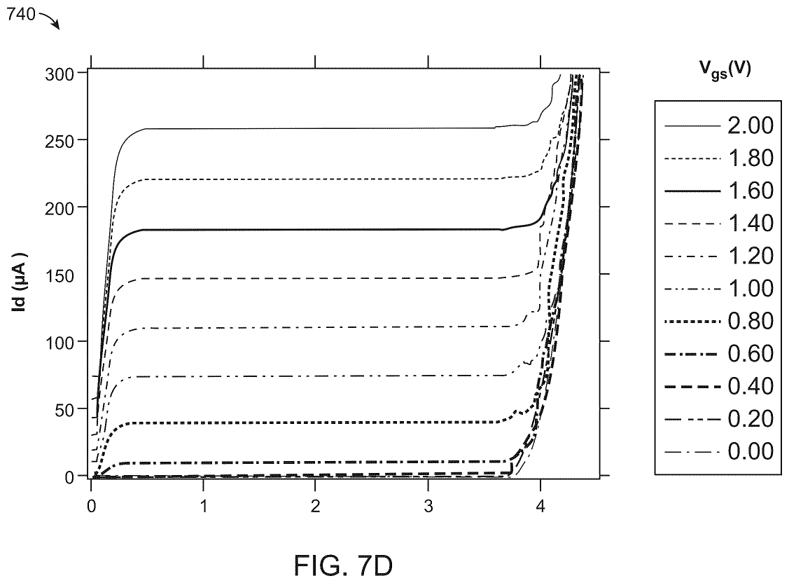

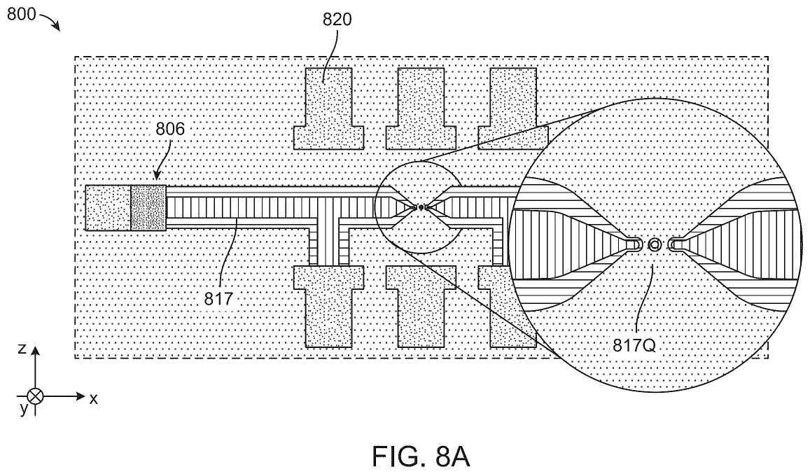

FIGS. 7A, 7B, 7C, and 7D illustrate plots of waveforms associated with the semiconductor device 600, in accordance with some embodiments. More specifically, a plot 710 of FIG. 7A shows a resistance-voltage (R-V) curve associated with the device 600 at room temperature (e.g., 300 K), a plot 720 of FIG. 7B shows a resistance-voltage (R-V) curve associated with the device 600 at low temperature (e.g., 2 K), a plot 730 of FIG. 7C shows a current-voltage (I-V) curve associated with the device 600 at room temperature (e.g., 300 K), and a plot 740 of FIG. 7D shows a current-voltage (I-V) curve associated with the device 600 at low temperature (e.g., 2 K). Referring to FIG. 6A, when the first gate signal 680 (VGate<Vth) is applied, the device 600 can be in an off state. In the device 600 of the off state, a charge carrier flow is not formed at the interface 612. The device 600 has a higher resistance between S/D structures 606 and thus do not conduct current therebetween, as shown in FIGS. 7A, 7B, 7C, and 7D. Referring to FIG. 6B, when the second gate signal 685 (VGate>Vth) is applied, the device 600 can be in an on state. In the device 600 of the on state, the second gate signal 685 can provide a conductive path 617C with a voltage high enough to form a charge carrier flow 612C at the interface 612, and thus conduct current between the S/D structures 606, as shown in FIGS. 7A, 7B, 7C, and 7D. In some examples, the device 600 and the techniques disclosed herein can be configured to operate at low temperature (e.g., 2 K) as shown in FIG. 7B and FIG. 7D, as well as room temperature (e.g., 300 K) as shown in FIG. 7A and FIG. 7C. For example, as discussed above, the device 600 can be configured to operate as a FET device. The device 600 can be configured to operate as an enhancement mode n-channel FET device. In some examples, based on the charge carrier flow 612C at the interface 612, the substrate 602 (e.g., device region therein, or otherwise any electronic platform) can be controlled.

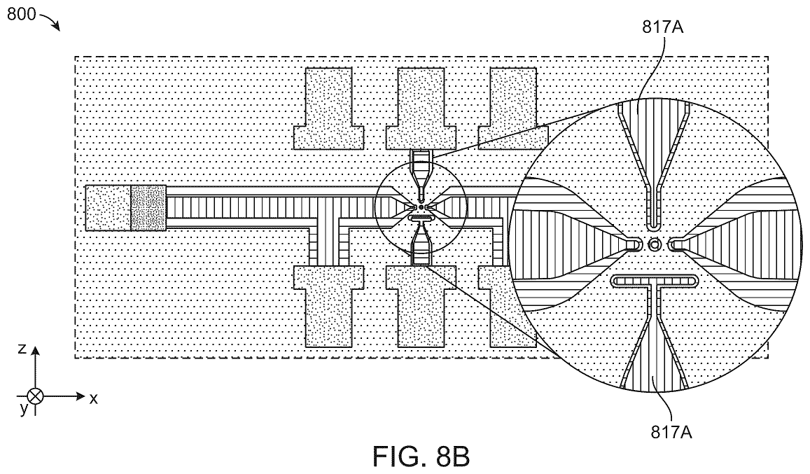

FIG. 8A illustrates a schematic diagram of an example of a semiconductor device 800, in accordance with some embodiments. More specifically, FIG. 8A shows a top view of a portion of the semiconductor device 800. The device 800 may be substantially similar to or incorporate features of the device 100. In some examples, the device 800 includes S/D structures 806 and a conducting structures 820, which may be substantially similar to or incorporate features of the S/D structures 106 and the conducting structure 120, respectively. Shown in FIG. 8A is a non-limiting example of the device 800. In some examples, the device 800 can include more, fewer, or different components than shown in FIG. 8A.

As shown in FIG. 8A, a conductive path 817 can be formed at an interface between a first structure (not shown; e.g., the first structure 110) and a second structure (not shown; e.g., the second structure 115) of the device 800. In some examples, the conductive path 817 can serve as a gate, when the device 800 is configured to operate as a FET device. When a voltage is applied through the conducting structures 820, the conductive path 817 can become conductive. Along the conductive path 817, a charge carrier flow can be generated and/or controlled below the first structure (at an interface, not shown; e.g., the interface 112). In some examples, the conductive path 817 can be designed, formed, or configured in various manners to generate and/or control the charge carrier flow. For example, a programming signal can be applied to form the conductive path 817 in a way that controls the charge carrier flow.

In some examples, the conductive path 817 can be formed and/or configured to generate and/or control electrons at a single electron level for the charge carrier. That is, along the conductive path 817, electrons can be generated and/or controlled one electron at a time, below the first structure. In some examples, the conductive path 817 can include a feature 817Q that facilitates a generation and/or control of single electrons below the first structure.

FIG. 8B illustrates a schematic diagram of the semiconductor device 800, in accordance with some embodiments. More specifically, FIG. 8B shows the device 800 in which a secondary conductive path 817A is additionally incorporated, as opposed to the device 800 of FIG. 8A. Shown in FIG. 8B is a non-limiting example of the device 800. In some examples, the device 800 can include more, fewer, or different components than shown in FIG. 8B.

In some examples, the secondary conductive path 817A can be configured to modulate the charge carrier flow below the first structure of the device 800. In some examples, as shown in FIG. 8B, the secondary conductive path 817A can be controlled through one or more of the conducting structures 820. That is, through a signal communicated through the conducting structures 820, the conductive path 817, and thus the charge carrier flow below the first structure, can be accessed, controlled, modulated, or otherwise configured for device operations. In some examples, the secondary conductive path 817A can be configured to control the charge carrier (e.g., holes, electrons), single electrons, etc. For example, a rate, a timing, etc. in generating and/or controlling single electrons can be controlled.

As described with respect to FIG. 8A and FIG. 8B, the techniques disclosed herein can enable the integration of semiconductor devices with quantum technologies. A single electron transistor can be achieved by generating and/or controlling a quantum dot through various features (e.g., the feature 817Q) and can enable various applications (e.g., a graphene nano ribbon (GNR)-based charge sensor). For example, a feature that provides a tunability of single electrons can be defined by the programming signals (e.g., ULV-EBL, c-AFM, etc.).

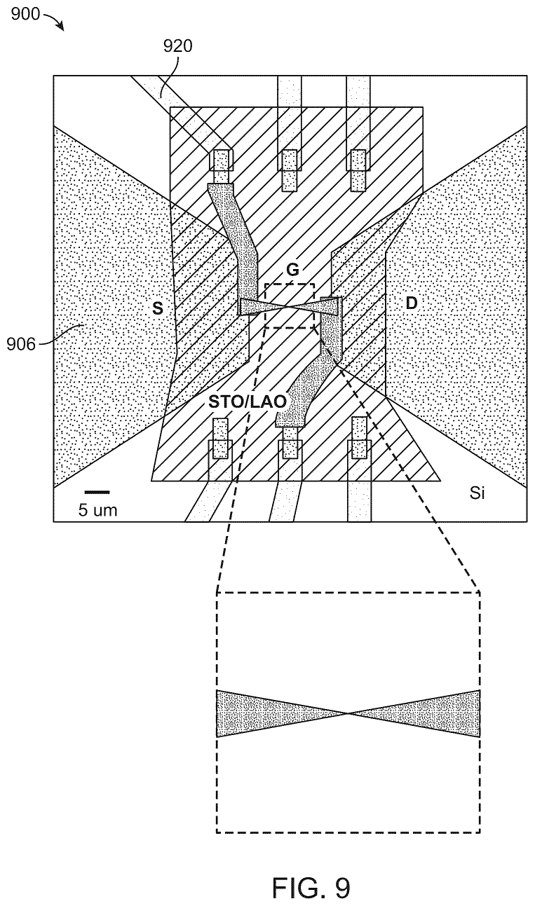

FIG. 9 illustrates a schematic diagram of an example of a semiconductor device 900, in accordance with some embodiments. The device 900 may be substantially similar to or incorporate features of the device 100. In some examples, the device 900 includes S/D structures 906 and a conducting structures 920, which may be substantially similar to or incorporate features of the S/D structures 106 and the conducting structure 120, respectively. Shown in FIG. 9 is a non-limiting example of the device 900. In some examples, the device 900 can include more, fewer, or different components than shown in FIG. 9.

In some embodiments, the device 900 of FIG. 9 can be configured as a reconfigurable single-electron transistor (SET). The device 900 can include source, drain, and gate elements defined within the membrane and the underlying phosphorous-doped silicon region. A nanoscale top-gate pattern can be written at the interface (e.g., STO/LAO) of the membrane using programming signals (e.g., ULV-EBL, c-AFM lithography, etc.) and include a plurality of nanowire segments, each separated by a small angel (e.g., 0.6 degree) and intersecting at a single central point. These intersecting conductive regions can overlap the source and drain contacts of the P-doped Si layer, thereby electrostatically defining a quantum dot at the nanowire intersection. In some embodiments, low-temperature transport measurements can be performed (e.g., at 50 mK) to confirm two conductance peaks in the source-drain conductance versus gate bias characteristic of Coulomb blockade resonant tunneling through the quantum dot. The observation of discrete Coulomb peaks and their tunability with the c-AFM defined gate network can demonstrate the membrane's reconfigurability and its capability for creating programmable single-electron devices, advancing both nanoelectronic applications and fundamental quantum-transport studies.

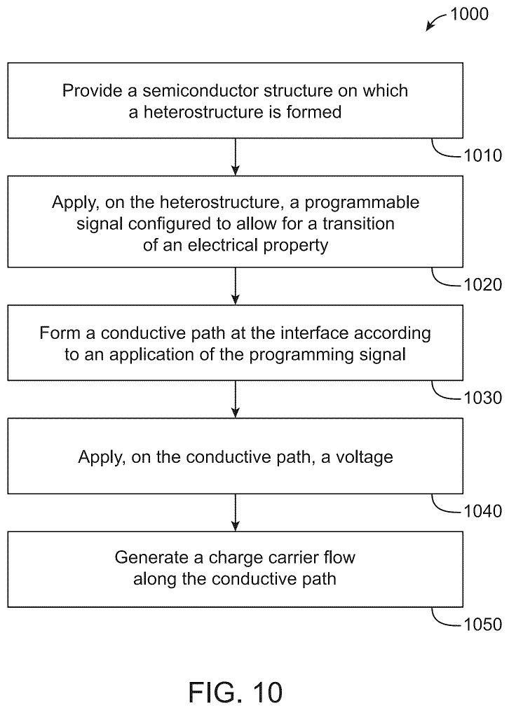

FIG. 10 illustrates a flowchart of an example method 1000 for a semiconductor device, in accordance with some embodiments. The method 1000 may be performed by one or more components of the device 100, the device 600, the device 800, etc. In some examples, the method 1000 may be performed by other entities. In some examples, the method 1000 includes more, fewer, or different operations than shown in FIG. 10.

In a brief overview, the method 1000 can start with operation 1010 of providing a semiconductor structure on which a heterostructure is formed, the heterostructure including a La-based structure and a Sr-based structure formed thereon. The method 1000 can continue to operation 1020 of applying, on the heterostructure, a signal to cause a transition of an electrical property of an interface between the La-based structure and the Sr-based structure. The method 1000 can continue to operation 1030 of forming a conductive path at the interface according to an application of the programming signal. The method 1000 can continue to operation 1040 of applying, on the conductive path, a voltage. The method 1000 can continue to operation 1050 of generating a charge carrier flow below the La-based structure, along the conductive path.

At operation 1010, a semiconductor structure (e.g., the device 100) can be provided. The semiconductor structure can include a heterostructure including a La-based structure (e.g., the first structure 110) and a Sr-based structure (e.g., the second structure 115) formed on the La-based structure. For example, the La-based structure can be an oxide structure including La (e.g., LAO). The Sr-based structure can be an oxide structure including Sr (e.g., STO). In some examples, the semiconductor structure includes a silicon substrate (e.g., the substrate 102) on which the heterostructure is formed. In some examples, the heterostructure can be a freestanding membrane structure. In some examples, a first portion and a second portion of the semiconductor structure adjacent to a bottom surface of the La-based structure can be doped to form source/drain structures (e.g., the S/D structures 106). In some examples, the La-based structure is thinner than the Sr-based structure. In some examples, a thickness of the Sr-based structure is thinner than about 50 nm. In some examples, the La-based structure is stacked on the substrate of the semiconductor structure through a van der Waals force. In some examples, the semiconductor structure can be configured to operate as a field effect transistor (FET), and the La-based structure can be configured to serve as a barrier of the FET.

At operation 1020, a programming signal (e.g., the programming signal 270) can be applied on the heterostructure. The programming signal can be configured to cause a transition (e.g., a switch) of an electrical property of an interface (e.g., the interface 117) between the La-based structure and the Sr-based structure. For example, the programming signal 270 can cause an electronic property of the interface to switch from being an insulating property to a conductive property or vice versa. In some examples, the programming signal can be generated by electron beam lithography or atomic force microscopy lithography. As a non-limiting example, an electron beam lithography system can focus and align an electron beam using patterned markers at the edge of the substrate. During writing and/or measurements, high vacuum environment may be maintained. The electron acceleration voltage, beam current, and/or electron dose may be adjusted to focus and align the electron beam, while the conductance is monitored. With an increase in conductance, the formation of a conductive channel (e.g., the conductive path) at the interface (e.g., STO/LAO) may be confirmed. After deactivating the electron beam, the conductance decay may be observed.

At operation 1030, a conductive path (e.g., the conductive path 217) is formed at the interface (e.g., the interface 117) according to an application of the programming signal. In some examples, the conductive path can include a secondary conductive path configured to access, control, modulate, or otherwise configure a charge carrier below the La-based structure. For example, the secondary conductive path can be configured to control the charge carrier (e.g., holes, electrons), single electrons, etc. For example, a rate, a timing, etc. in generating and/or controlling single electrons can be controlled. As a non-limiting example, a c-AFM lithography can be used to program and/or reconfigure the conductive path. For example, the conductive path at the STO/LAO interface can be programmatically adjusted by altering its electrical properties using a biased c-AFM tip. The method can include scanning the tip (e.g., biased at a predetermined voltage) across the top surface of the second structure (e.g., the STO surface). For instance, a positive bias can render a scanned region conductive, while a negative bias can render a scanned region insulating.

At operation 1040, a voltage is applied on the conductive path. In some examples, the voltage can be adjusted to operate the semiconductor structure as a FET device. For example, a voltage lower than a threshold voltage of the semiconductor structure can be applied to operate the semiconductor structure in an off state. A voltage higher than the threshold voltage of the semiconductor structure can be applied to operate the semiconductor structure in an on state.

At operation 1050, a charge carrier flow (e.g., the charge carrier flow 212) can be generated along the conductive path below the La-based structure. In some examples, the charge carrier is a two-dimensional electron gas. In some examples, the charge carrier includes electrons or holes. In some examples, the charge carrier includes single electrons, and the conductive path is configured to control the single electrons at the single electron level.

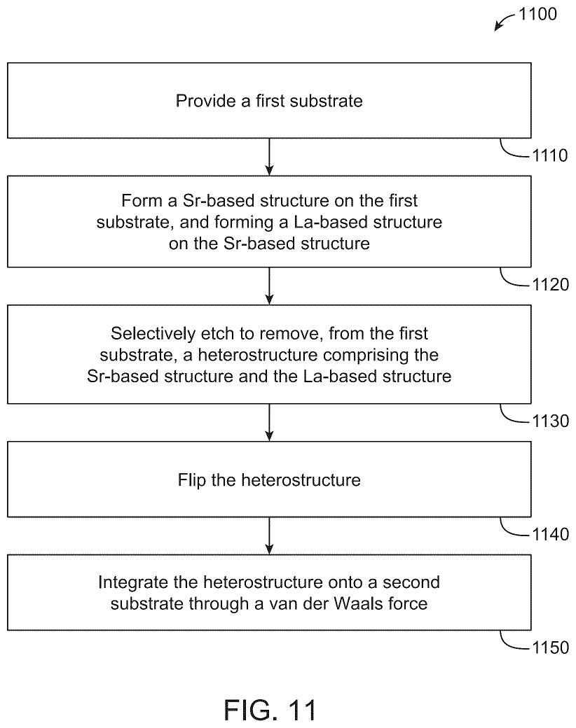

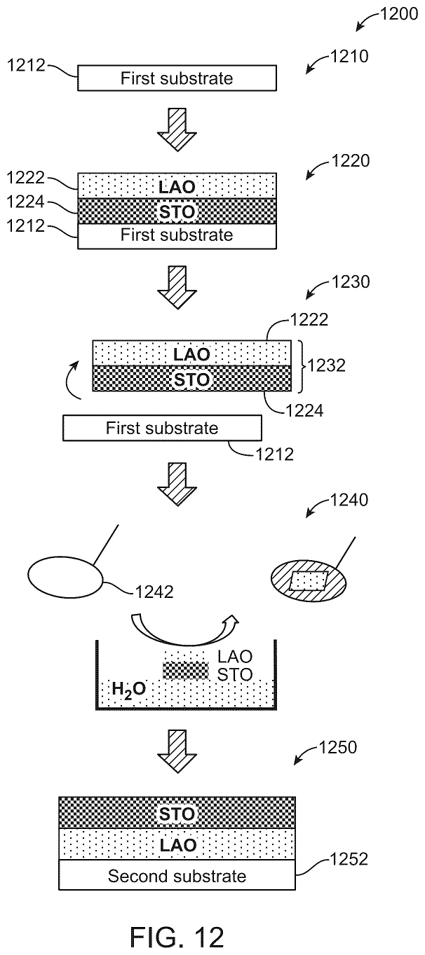

FIG. 11 illustrates a flowchart of an example method 1100 for a semiconductor device, in accordance with some embodiments. FIG. 12 illustrates a schematic flow diagram 1200 of the method 1100 for a semiconductor device, in accordance with some embodiments.

In a brief overview, the method 1100 can start with operation 1110 of providing a first substrate. The method can continue to operation 1120 of forming a Sr-based structure on the first substrate, and forming a La-based structure on the Sr-based structure. The method can continue to operation 1130 of selectively etching to remove, from the first substrate, a heterostructure including the Sr-based structure and the La-based structure. The method can continue to operation 1140 of manipulating (e.g., inverting such as by flipping) the heterostructure. The method can continue to operation 1150 of integrating the heterostructure onto a second substrate through a van der Waals force.

At operation 1110, as illustrated in a diagram 1210 of FIG. 12, a first substrate 1212 is provided. The first substrate 1212 can be or include a structure or layer on which the material of a Sr-based structure 1224 (e.g., the second structure 115) can be disposed (e.g., grown). For example, the first substrate 1212 can be or include a structure on which the material of the Sr-based structure 1224 can be epitaxially deposited. In some examples, the first substrate 1212 can be an STO substrate with a sacrificial layer (e.g., Sr₃Al₂O₆, etc.). In some examples, the first substrate 1212 can be sapphire, aluminum oxide, silicon oxide, etc. The first substrate 1212 can be or include a multi-layer structure, for example, including but not limited to, a sacrificial layer (e.g., Sr₃Al₂O₆,), on a substrate (e.g., STO), etc.

At operation 1120, as illustrated in a diagram 1220 of FIG. 12, the Sr-based structure 1224 (e.g., STO) can be formed on the first substrate 1212, and then a La-based structure 1222 (e.g., LAO) can be formed on the Sr-based structure 1224. In some examples, the Sr-based structure 1224 can be epitaxially deposited on the first substrate 1212. In some examples, the La-based structure 1222 can be epitaxially deposited on the Sr-based structure 1224. The Sr-based structure 1224 and the La-based structure 1222 can be formed in various manners. In some examples, the Sr-based structure 1224 and the La-based structure 1222 can be deposited by pulsed laser deposition or any other deposition methods, including but not limited to, chemical vapor deposition (CVD), physical vapor deposition (PVD), plasma enhanced CVD (PECVD), molecular beam epitaxy (MBE), metal organic CVD (MOCVD), or the like.

At operation 1130, as illustrated in a diagram 1230 of FIG. 12, a bottom portion of the Sr-based structure 1224 (or an upper portion of the first substrate 1212, an interface between the Sr-based structure 1224 and the first substrate 1212, etc.) can be selectively etched. That is, a heterostructure 1232 including a top portion of the Sr-based structure 1224 and the La-based structure 1222 formed thereon can be removed from the first substrate 1212. In some examples, when the Sr-based structure 1224 is formed on a sacrificial layer (e.g., Sr₃Al₂O₆, etc.) of the first substrate 1212, the sacrificial layer can be selectively etched. For example, a water-soluble material can be used for the sacrificial layer, and the heterostructure 1232 including the Sr-based structure 1224 and the La-based structure 1222 can be selectively removed from the first substrate 1212. In some examples, any etchant that can selectively remove the heterostructure 1232 from the first substrate 1212 while not affecting the heterostructure 1232 (e.g., physical and chemical properties thereof) can be used.

At operation 1140, as illustrated in a diagram 1240 of FIG. 12, the heterostructure 1232 can be inverted. In some examples, the heterostructure 1232, selectively etched and removed from the first substrate 1212, can be inverted and collected such that the La-based structure 1222 is positioned below the Sr-based structure 1224. In some examples, at operation 1140, the method 1100 can include, selectively etching the heterostructure 1232 and retrieving the heterostructure 1232 prior to manipulating the heterostructure. In some examples, the method 1100 can include using a wire loop 1242 to retrieve the heterostructure 1232.

At operation 1150, as illustrated in a diagram 1250 of FIG. 12, the heterostructure 1232, which has been inverted (hereinafter referred to as the inverted heterostructure 1232), can be integrated onto a second substrate 1252. In some examples, the inverted heterostructure 1232 can be bonded onto the second substrate 1252 through a van der Waals force.

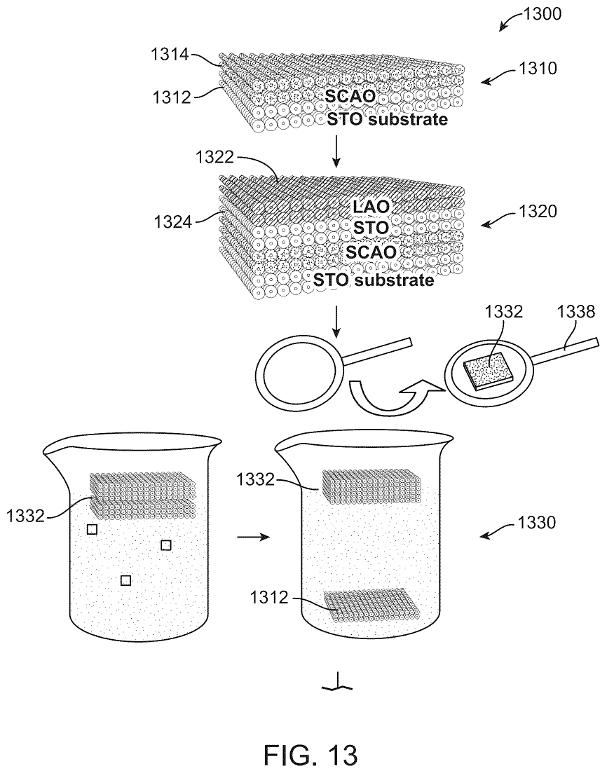

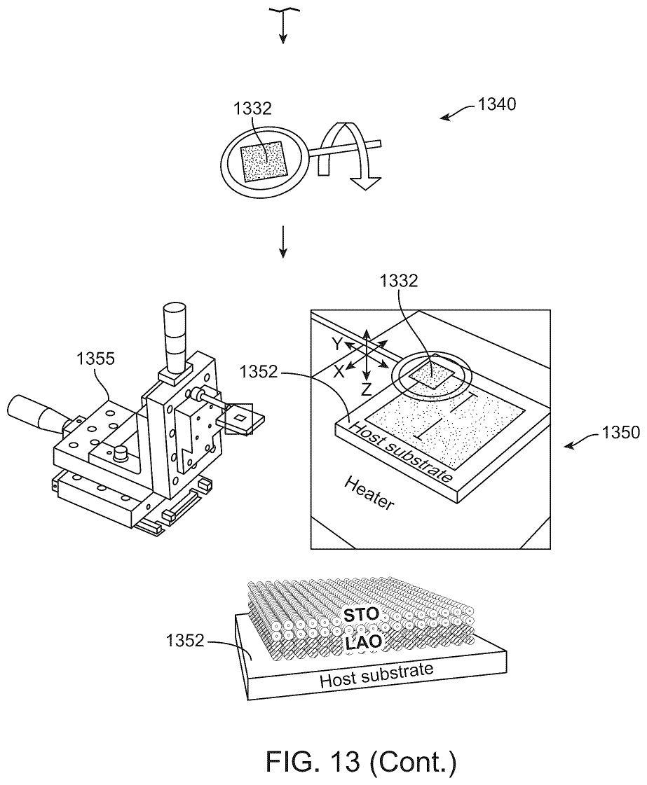

FIG. 13 illustrates a schematic flow diagram 1300 of an example of the method 1100 for a semiconductor device, in accordance with some embodiments.

At operation 1110, as illustrated in a diagram 1310 of FIG. 13, a first substrate 1312 is provided. The first substrate 1312 can be or include a structure or layer on which the material of a Sr-based structure 1324 (e.g., the second structure 115) can be grown. For example, the first substrate 1312 can be or include a structure on which the material of the Sr-based structure 1324 can be epitaxially deposited. In some examples, as shown, the first substrate 1312 can be an STO substrate with a sacrificial layer 1314 (e.g., Sr₃Al₂O₆, etc.). In some examples, the first substrate 1312 can be sapphire, aluminum oxide, silicon oxide, etc. The first substrate 1312 can be or include a multi-layer structure, for example, including but not limited to, the sacrificial layer 1314 (e.g., Sr₃Al₂O₆,), on a substrate (e.g., STO), etc. The use of Sr₃Al₂O₆ as the sacrificial layer 1314 in the fabrication of inverted STO/LAO membranes can offer advantages due to its water solubility and ability to fine-tune the lattice constant by substituting Sr with smaller Ca ions, achieving a lattice constant of 3.907 Å. This adjustment mitigates the lattice mismatch between the LAO/STO heterostructure and the sacrificial layer 1314, minimizing dislocation density and suppressing major crack formation during membrane release, thus contributing to a high-quality inverted membrane.

At operation 1120, as illustrated in a diagram 1320 of FIG. 13, the Sr-based structure 1324 (e.g., STO) can be formed on the first substrate 1312, and then a La-based structure 1322 (e.g., LAO) can be formed on the Sr-based structure 1324. In some examples, the Sr-based structure 1324 can be epitaxially deposited on the first substrate 1312. In some examples, the La-based structure 1322 can be epitaxially deposited on the Sr-based structure 1324. The Sr-based structure 1324 and the La-based structure 1322 can be formed in various manners. In some examples, the Sr-based structure 1324 and the La-based structure 1322 can be deposited by pulsed laser deposition or any other deposition methods, including but not limited to, chemical vapor deposition (CVD), physical vapor deposition (PVD), plasma enhanced CVD (PECVD), molecular beam epitaxy (MBE), metal organic CVD (MOCVD), or the like.

In some examples, the first substrate 1312 can be a STO (001) substrate, and the STO/SCAO layers can be grown thereon, facilitating LAO growth on the STO/SCAO layers. Epitaxial thin film growth techniques, such as pulsed laser deposition (PLD) with in situ high-energy electron diffraction (RHEED) monitoring, can be employed for growing LAO, STO, and/or SCAO thin films on (001)-oriented STO substrates. These structures can be prepared by etching in buffered hydrofluoric acid (BHF) and then annealed at elevated temperatures in an oxygen atmosphere to achieve a TiO₂-terminated surface with a stepped morphology. During the growth of the SCAO and STO layers, specific temperature and oxygen partial pressure conditions can be maintained to optimize layer formation. Following the growth, cooling under controlled oxygen ambience can ensure the template's structural integrity.

At operation 1130, as illustrated in a diagram 1330 of FIG. 13, a bottom portion of the Sr-based structure 1324 (or an upper portion of the first substrate 1312, an interface (e.g., the sacrificial layer 1314) between the Sr-based structure 1324 and the first substrate 1312, etc.) can be selectively etched. In some examples, when the Sr-based structure 1324 is formed on the sacrificial layer 1314 of the first substrate 1312, the sacrificial layer 1314 can be selectively etched. For example, a water-soluble material can be used for the sacrificial layer 1314, and the heterostructure 1332 (sometimes referred to as the membrane 1332) including the Sr-based structure 1324 and the La-based structure 1322 can be selectively removed from the first substrate 1312. In some examples, any etchant that can selectively remove the heterostructure 1332 from the first substrate 1312 while not affecting the heterostructure membrane 1332 (e.g., physical and chemical properties thereof) can be used. In some examples, these membrane release and transfer steps can include selective etching of SCAO as the sacrificial layer 1314, where samples are floated on deionized water to release the LAO/STO heterostructure membrane 1332. A wire loop 1338 (e.g., a nichrome wire loop) can be used to collect the membrane 1332, assisted by water's surface tension.

At operation 1140, as illustrated in a diagram 1340 of FIG. 13, the heterostructure 1332 can be inverted using the wire loop 1338. The wire loop 1338 can be used to carefully invert the membrane 1332, ensuring the desired inverted configuration for integration with a host. In some examples, the heterostructure 1332, selectively etched and removed from the first substrate 1312, can be inverted and collected such that the La-based structure 1322 is positioned below the Sr-based structure 1324. Based on this approach, the transferable inverted STO/LAO heterostructure 1332 can be created. This ensures direct contact between the LAO layer and the host substrate at downstream, which precludes the use of mechanical supports like polymer layers such as PDMS or PET.

At operation 1150, as illustrated in a diagram 1350 of FIG. 13, the heterostructure 1332, which has been inverted (hereinafter referred to as the inverted heterostructure 1332), can be integrated onto a host (e.g., a second substrate 1352). In some examples, the inverted heterostructure 1332 can be bonded onto the second substrate 1352 through a van der Waals force.

In some examples, the integration of the inverted heterostructure onto the second substrate 1352 can be achieved through the precise use of a micromanipulator system 1355. The micromanipulator system 1355 can be configured to accurately align the freestanding membrane 1332 during transfer by allowing for fine adjustments along the x-and y-axes. The wire loop 1338 holding the inverted membrane 1332 can be mounted to the micromanipulator system 1355, and once the targeted position on the second substrate 1352 is confirmed, the wire loop 1338 can be gradually lowered to deposit the inverted membrane 1332. In some examples, post-transfer heating can be applied to enhance adhesion without compromising the functionality of the single crystal oxide membranes.

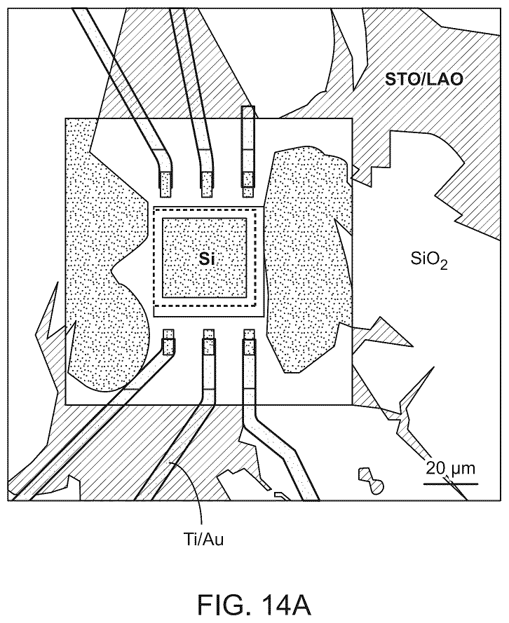

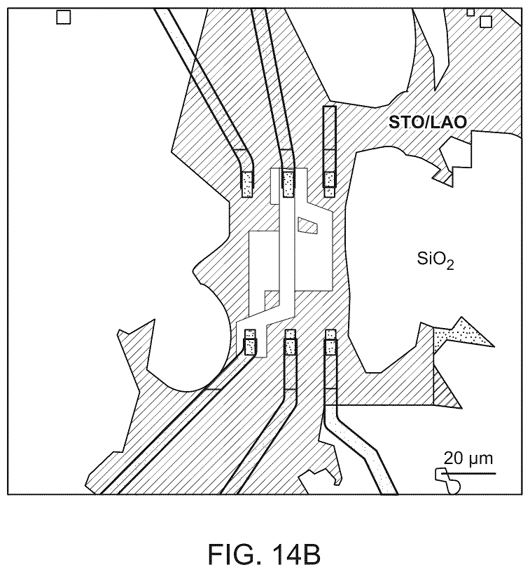

FIG. 14A illustrates an example configuration of an inverted membrane (e.g., the inverted membrane 1332) that has been transferred onto a second substrate (e.g., the second substrate 1352, a patterned Si substrate), in accordance with some embodiments. As a non-limiting example, FIG. 14A shows the image of the membrane formed of STO (44 nm) and LAO (10 unit cells). In FIG. 14A, the membrane is aligned using a micromanipulator system (e.g., the micromanipulator system 1355). On the second substrate, interface electrodes were formed using controlled Ar+ion milling followed by Ti/Au electrode sputter deposition. These contact structures can be used to measure the membrane's electrical tunability (e.g., conductance measurement to monitor the transition between conducting and insulating properties). FIG. 14B illustrates a non-limiting, alternative example configuration of the inverted membrane of FIG. 14A, in accordance with some embodiments. For example, shown in FIG. 14B may represent a scanning-electron microscopy image. This image demonstrates intactness post-processing while showing minor crack formations. Techniques, such as High-Angle Annular Dark-Field Scanning Transmission Electron Microscopy (STEM-HAADF), can be used to confirm the dislocation-free interface and verify the high crystal quality of the inverted membrane. For example, the inverted membrane and the second substrate can have an atomically smooth surface with step-terrace morphology, indicating potential strain relaxation while confirming the preservation of high quality post-integration.

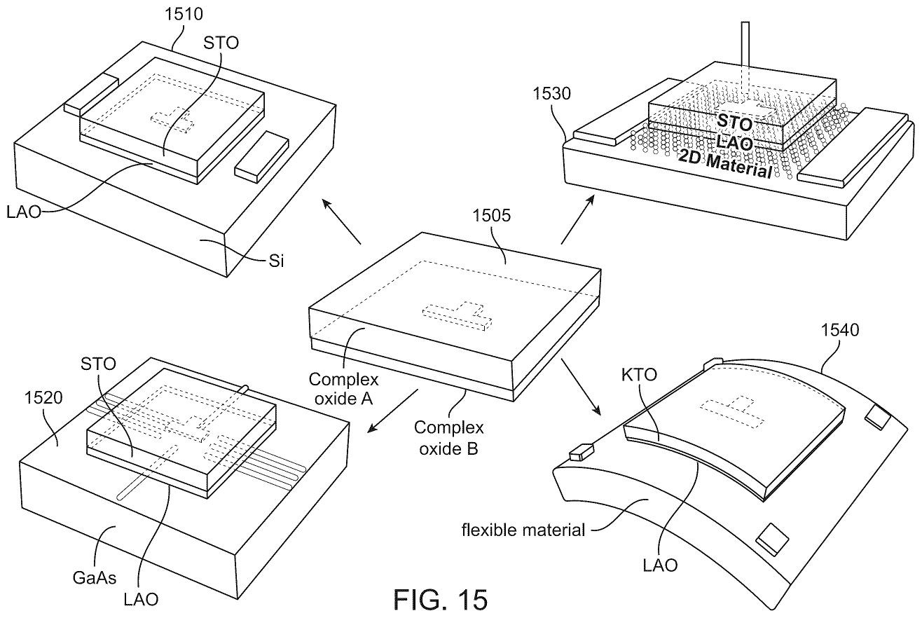

FIG. 15 illustrates non-limiting example applications of an inverted membrane 1505 across various material platforms, in accordance with some embodiments. As shown, the inverted membrane 1505 can be integrated with a Si platform 1510, leading to the development of reprogrammable Si-based FET devices and single-electron transistors, where the ultrathin layer (e.g., LAO) acts as the gate dielectric, while the heterostructure interface (e.g., STO/LAO interface) provides conducting channels for precise carrier control. The inverted membrane 1505 can be integrated with a III-V (e.g., GaAs) platform 1520 to electrostatically control quantum dots or spin qubits, aiding quantum applications. The inverted membrane 1505 can be integrated with a two-dimensional material 1530, such as MoS₂, and integrated with photonic devices, leveraging the dielectric properties of the Sr-based material (e.g., STO) and the wide bandgap of La-based material (e.g., LAO) for advanced optoelectronics. The inverted membrane 1505 can be integrated with a flexible material platform 1540, promoting the creation of reconfigurable flexible electronics possessing multifunctional oxide attributes. This versatility demonstrates the transformative potential of inverted oxide heterostructures in nanoelectronic, quantum, and photonic advancements.

Directional terms as used herein-for example up, above, below, down, right, left, front, back, top, bottom, vertical, horizontal-are made only with reference to the figures as drawn and are not intended to imply absolute orientation unless otherwise expressly stated.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise. Also, the word “or” when used without a preceding “either” (or other similar language indicating that “or” is unequivocally meant to be exclusive—e.g., only one of x or y, etc.) shall be interpreted to be inclusive (e.g., “x or y” means one or both x or y).

The term “and/or” shall also be interpreted to be inclusive (e.g., “x and/or y” means one or both x or y). In situations where “and/or” or “or” are used as a conjunction for a group of three or more items, the group should be interpreted to include one item alone, all the items together, or any combination or number of the items. Moreover, terms used in the specification and claims such as have, having, include, and including should be construed to be synonymous with the terms comprise and comprising. Other elements may optionally be present other than the elements specifically identified by the “and/or” clause, whether related or unrelated to those elements specifically identified. As a non-limiting example, a reference to “X and/or Y” may refer, in one embodiment, to X only (optionally including elements other than Y); in some embodiments, to Y only (optionally including elements other than X); in yet some embodiments, to both X and Y (optionally including other elements).

The drawings may be interpreted, for example, as showing: (a) everything drawn to scale, (b) nothing drawn to scale, or (c) one or more features drawn to scale and one or more features not drawn to scale. Accordingly, the drawings may serve to provide support to recite the sizes, proportions, and/or other dimensions of any of the illustrated features either alone or relative to each other. Furthermore, all such sizes, proportions, and/or other dimensions are to be understood as being variable from 0%-100% in either direction and thus provide support for claims that recite such values or any and all ranges or subranges that may be formed by such values.

References to specific examples, use of “i.e.,” use of the word “invention,” etc., are not meant to invoke exception (b) or otherwise restrict the scope of the recited claim terms. Other than situations where exception (b) applies, nothing contained in this document should be considered a disclaimer or disavowal of claim scope.

Unless the context indicates otherwise, it is specifically intended that the various features of the disclosure described herein may be used in any combination. Moreover, the disclosure also contemplates that in some embodiments, any feature or combination of features set forth herein may be excluded or omitted. To illustrate, if the specification states that a device comprises components A, B and C, any of A, B or C, or a combination thereof, may be omitted and disclaimed singularly or in any combination.

As used herein, “about” or “approximately” will be understood by persons of ordinary skill in the art and will vary to some extent depending upon the context in which it is used. If there are uses of the term which are not clear to persons of ordinary skill in the art, given the context in which it is used, “about” or “approximately” will mean up to plus or minus 10% of the particular term.

While certain embodiments have been illustrated and described, it should be understood that changes and modifications may be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations may be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, which may of course vary. It is also to be understood that the terminology used herein is for the purpose of describing particular embodiments only, and is not intended to be limiting.

As will be understood by one skilled in the art, for any and all purposes, particularly in terms of providing a written description, all ranges disclosed herein also encompass any and all possible subranges and combinations of subranges thereof, inclusive of the endpoints. As such, all disclosed ranges are to be understood to encompass and provide support for claims that recite any and all subranges or any and all individual values subsumed by each range. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

Any listed range may be easily recognized as sufficiently describing and enabling the same range being broken down into at least equal halves, thirds, quarters, fifths, tenths, etc. As a non-limiting example, each range discussed herein may be readily broken down into a lower third, middle third and upper third, etc. As will also be understood by one skilled in the art all language such as “up to,” “at least,” “greater than,” “less than,” and the like, include the number recited and refer to ranges which may be subsequently broken down into subranges as discussed above. Further, as will be understood by one skilled in the art, a range includes each individual member. Thus, for example, a group having 1-3 layers refers to groups having 1, 2, or 3 layers. Similarly, a group having 1-5 layers refers to groups having 1, 2, 3, 4, or 5 layers, and so forth.

Any publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure. Other embodiments are set forth in the following claims.

What is claimed is:

1. A structure, comprising:
a semiconductor substrate;
a first oxide structure disposed above the semiconductor substrate;
a second oxide structure disposed above the first oxide structure and configured to form a conductive path at an interface between the first oxide structure and the second oxide structure; and
a conducting structure extending from the interface through the second oxide structure, the conducting structure being configured such that, in response to a voltage being applied to the conducting structure, wherein the conducting structure causes a charge carrier to be generated below the second oxide structure along the conductive path.

2. The structure of claim 1, wherein the first oxide structure comprises La, Al, and O, and the second oxide structure comprises Sr, Ti, and O.

3. The structure of claim 1, wherein the first oxide structure and the second oxide structure form a freestanding membrane structure.

4. The structure of claim 1, wherein the conducting structure is further configured such that in response to the voltage being applied to the conducting structure, electrons of the charge carrier are individually controllable.

5. The structure of claim 4, wherein the conductive path includes a secondary conductive path to control the electrons.

6. The structure of claim 1, wherein the structure is configured as a field effect transistor (FET), and the FET is (i) in an off state in response to the voltage being lower than a threshold voltage, and (ii) in an on state in response to the voltage being higher than the threshold voltage.

7. The structure of claim 1, wherein the first oxide structure is thinner than the second oxide structure.

8. The structure of claim 1, wherein the conductive path is configured to be formed based on a signal at a first voltage level and be erased based on a signal at a second voltage level.

9. A device, comprising:
a substrate;
a La-based structure disposed above the substrate;
a Sr-based structure disposed above the La-based structure; and
a source structure and a drain structure adjacent to a bottom surface of the La-based structure;
wherein an interface between the La-based structure and the Sr-based structure is configured to form a conductive path in response to a signal to cause a transition of an electrical property of the interface; and
wherein in response to a voltage applied to the conductive path, the conductive path is configured to cause a charge carrier flow to be generated below the La-based structure.

10. The device of claim 9, wherein the substrate comprises one of: (i) silicon, II-VI compounds, or III-V compounds, (ii) an electronic device, a photonic device, an optoelectronic device, a quantum device, or a single electron device, and (iii) a two-dimensional (2D) material or a flexible material.

11. The device of claim 9, wherein the signal is generated by electron beam lithography or atomic force microscopy lithography.

12. The device of claim 9, wherein a portion of the interface is configured to, (i) in response to the signal being provided on the portion of the interface at a first voltage level, have a first conductivity, and (ii) in response to the signal being provided on the portion of the interface at a second voltage level, have a second conductivity, wherein the second conductivity is lower than the first conductivity.

13. The device of claim 9, wherein the La-based structure is stacked on the substrate through a van der Waals force.

14. The device of claim 9, wherein the device is a field effect transistor (FET), and the La-based structure is to serve as a barrier of the FET.

15. The device of claim 9, wherein the La-based structure and the Sr-based structure forms a freestanding membrane structure configured to be transferrable to another substrate.

16. A method, comprising:
providing a first substrate;
forming a Sr-based structure on the first substrate;
forming a La-based structure on the Sr-based structure;
selectively etching to remove, from the first substrate, a heterostructure comprising the Sr-based structure and the La-based structure;
manipulating the heterostructure; and
integrating the heterostructure onto a second substrate through a van der Waals force.

17. The method of claim 16, comprising epitaxially growing the Sr-based structure and the La-based structure.

18. The method of claim 16, comprising applying a signal, using electron beam lithography or atomic force microscopy lithography, to form a conductive path at an interface between the Sr-based structure and the La-based structure.

19. The method of claim 16, wherein the first substrate includes a sacrificial layer on which the Sr-based structure is formed, and the selectively etching includes etching the sacrificial layer.

20. The method of claim 16, wherein the manipulating includes:
retrieving the removed heterostructure using a wire loop;
inverting the retrieved heterostructure using the wire loop; and
positioning, using a micromanipulator system, the inverted heterostructure on the second substrate.
